(19) United States
(12) Patent Application Publication
(10) Pub. No.: US 2026/0005690 A1
(43) Pub. Date: Jan. 1, 2026

(54) SERIAL PERIPHERAL INTERFACE

(71) Applicant: TEXAS INSTRUMENTS INCORPORATED, Dallas, TX (US)

(72) Inventors: Xiaochun ZHAO, Allen, TX (US); Eung Jung KIM, Allen, TX (US)

(21) Appl. No.: 18/759,930

(22) Filed: Jun. 30, 2024

(51) Int. Cl. H03K 17/687; H02H 9/04; H03K 5/01

(52) U.S. Cl. CPC H03K 17/6871; H02H 9/045; H03K 5/01; H03K 2217/0063

(57) ABSTRACT

A circuit includes a preregulator circuit. The preregulator circuit includes first and second transistors, and first and second Zener diodes. The first transistor has a first terminal, a second terminal, and a control terminal. The first Zener diode has a first terminal coupled to the second terminal of the first transistor, and a second terminal coupled to the control terminal of the first transistor. The second transistor has a first terminal coupled to the second terminal of the first transistor, a second terminal, and a control terminal coupled to the first terminal of the first transistor. The second Zener diode has a first terminal coupled to the control terminal of the second transistor, and a second terminal coupled to the second terminal of the first Zener diode.

### BACKGROUND

Electronic systems use serial interfaces to provide for transfer of data between connected devices. Serial peripheral interface (SPI) is one type of serial communication interface that provides synchronous transfer of data between a primary device, such as a microcontroller, and one or more peripherals (secondary devices). In SPI, the primary device generates a clock signal, a select signal, and an input data signal (e.g., data transferred to the secondary devices). The secondary devices receive the input data signal synchronous with the clock signal while the select signal is active, and generate, synchronous with the clock signal, a data output signal for reception by the primary device.

### SUMMARY

In one example, a circuit includes a preregulator circuit. The preregulator circuit includes first and second transistors, and first and second Zener diodes. The first transistor has a first terminal, a second terminal, and a control terminal. The first Zener diode has a first terminal coupled to the second terminal of the first transistor, and a second terminal coupled to the control terminal of the first transistor. The second transistor has a first terminal coupled to the second terminal of the first transistor, a second terminal, and a control terminal coupled to the first terminal of the first transistor. The second Zener diode has a first terminal coupled to the control terminal of the second transistor, and a second terminal coupled to the second terminal of the first Zener diode.

In another example, a circuit includes a preregulator circuit and an output buffer circuit. The preregulator circuit has a first terminal configured to receive a power supply voltage, a second terminal configured to receive a reference voltage, a first output configured to provide a regulated voltage, and a second output configured to provide an overvoltage signal. The output buffer circuit includes a first, second, and third transistors, a resistor, and a logic gate. The first transistor has a first terminal coupled to the second terminal of the preregulator circuit, a second terminal, and a control terminal. The second transistor has a first terminal coupled to the second terminal of the first transistor, a second terminal, and a control terminal. The third transistor has a first terminal coupled to the second terminal of the second transistor, a second terminal coupled to the first terminal of the preregulator circuit, and a control terminal. The resistor has a first terminal coupled to the second terminal of the preregulator circuit, and a second terminal coupled to the control terminal of the third transistor. The logic gate has a first input configured to receive an output signal, a second input coupled to the second output of the preregulator circuit, and an output coupled to the control terminal of the first transistor.

In a further example, a high-side switch circuit includes a high-side transistor, a control circuit, a preregulator circuit, an input buffer, and an output buffer. The high-side transistor has a first terminal configured to receive a first voltage, a second terminal configured to provide a second voltage to a load circuit; and a control terminal. The control circuit has a first output coupled to the control terminal of the high-side transistor; a second output, and an input. The preregulator circuit has a first terminal configured to receive a third voltage. The preregulator circuit is configured to pass the third voltage to an output terminal based on the third voltage being less than a first threshold, and limit the voltage at the output terminal to a second threshold based on the third voltage being greater than the second threshold. The input buffer circuit has a power terminal coupled to the output of the preregulator circuit, and an output coupled to the input of the control circuit. The output buffer circuit has a power terminal coupled to the input of the preregulator circuit, and an input coupled to the second output of the control circuit.

### BRIEF DESCRIPTION OF THE DRAWINGS

FIG. 1 is a block diagram of a high-side switch circuit that communicates via a serial peripheral interface and includes protection against negative power supply transients;

FIG. 2 is schematic diagram of an example preregulator circuit suitable for use in the high-side switch circuit of FIG. 1.

FIG. 3 is schematic diagram of an example input buffer circuit suitable for use in the high-side switch circuit of FIG. 1.

FIG. 4 is schematic diagram of an example output buffer circuit suitable for use in the high-side switch circuit of FIG. 1.

FIG. 5 is a block diagram of an example system that includes the high-side switch circuit of FIG. 1.

FIG. 6 is a graph of example signals in the system of FIG. 5.

### DETAILED DESCRIPTION

A serial bus, such as a serial peripheral interface (SPI) bus can be used to communicate with and control high-side switches and other peripheral devices in a variety of applications. For example, in automotive applications, use of the SPI bus to control multiple high-side switches can reduce controller and circuit board complexity. In such applications, the serial bus interface of the high-side switch should maintain consistent logic thresholds relative to the controller communicating with the high-side switch, which can be difficult in operational environments subject to power transients. Additionally, negative power supply transients can drive all internal nodes of the high-side switch negative, which can cause high current draw from the power supply powering the high-side switch and pull the power supply voltage negative. During such a transient, the power supply voltage provided to the high-side switch and the controller coupled to the high-side switch should remain higher than an under-voltage threshold so that the controller does not power down and lose stored information.

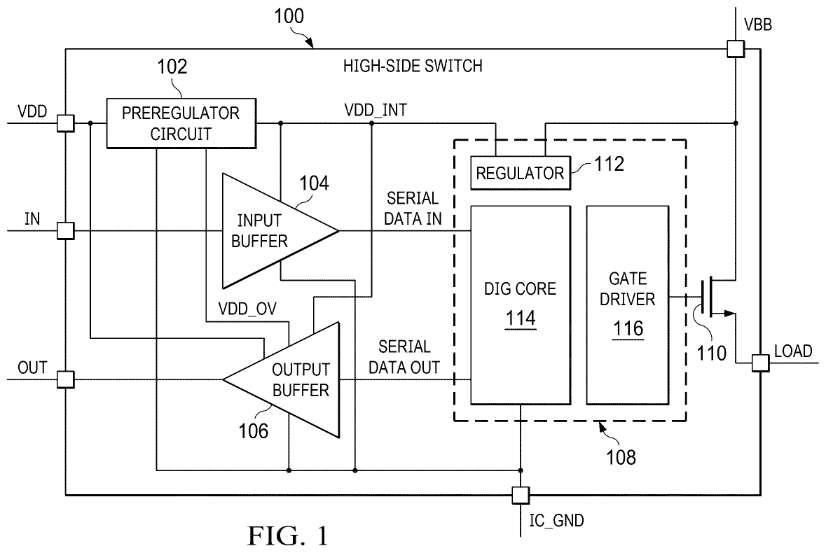

FIG. 1 is a block diagram of a high-side switch circuit 100 that communicates via a serial peripheral interface and includes protection against negative power supply transients. The high-side switch circuit 100 includes a preregulator circuit 102, an input buffer circuit 104, an output buffer circuit 106, a control circuit 108, and a high-side transistor 110. The high-side transistor 110 may be an n-channel field effect transistor (NFET). The high-side transistor 110 conducts current between a first power terminal (VBB) and a load terminal (LOAD). The high-side transistor 110 has a first terminal (e.g., drain) coupled to VBB, a second terminal (e.g., source) coupled to LOAD, and a control terminal (e.g., gate) coupled to the control circuit 108.

The control circuit 108 includes a regulator circuit 112, digital core circuitry 114, and a gate driver circuit 116. The gate driver circuit 116 provides an output signal with voltage and current suitable for turning the high-side transistor 110 on and off. An output of the gate driver circuit 116 is coupled to the control terminal of the high-side transistor 110. The regulator circuit 112 provides regulated voltage to the digital core circuitry 114. An input of the regulator circuit 112 is coupled to an output of the preregulator circuit 102 for receipt of power supply voltage processed by the preregulator circuit 102. The digital core circuitry 114 includes the logic circuitry for serial communication and control of the gate driver circuit 116. The digital core circuitry 114 receives serial communication signals (e.g., input data and/or clock) from the input buffer circuit 104, and provides a serial communication signal (output data) to the output buffer circuit 106.

The input buffer circuit 104 receives serial communication signals (e.g., input data or clock) transmitted by a controller, and provides the received signal to the digital core circuitry 114. An input of the input buffer circuit 104 is coupled to an input terminal (IN) of the high-side switch circuit 100, and an output terminal of the input buffer circuit 104 is coupled to an input of the digital core circuitry 114. While a single instance of the input buffer circuit 104 is shown for simplicity, the high-side switch circuit 100 may include a first example of the input buffer circuit 104 for receiving a clock signal and a second example of the input buffer circuit 104 for receiving input data. The input buffer circuit 104 has a power terminal coupled to the output of the preregulator circuit 102, and a reference terminal coupled to a reference terminal (IC_GND) of the high-side switch circuit 100. The input buffer circuit 104 includes protection circuitry that limits the voltage provided to internal circuitry of the input buffer circuit 104.

The output buffer circuit 106 receives serial data to be transmitted from the digital core circuitry 114, and transmits the serial data to the controller coupled to the high-side switch circuit 100. An input of the output buffer circuit 106 is coupled to an output of the digital core circuitry 114, and an output of the output buffer circuit 106 is coupled to an output terminal (OUT) of the high-side switch circuit 100. The output buffer circuit 106 has a first power terminal coupled to a power terminal (VDD) of the high-side switch circuit 100, a second power terminal coupled to an output power terminal (VDD_INT) of the preregulator circuit 102, and a reference terminal coupled to a reference terminal (IC_GND) of the high-side switch circuit 100. The output buffer circuit 106 includes high-voltage output circuitry that automatically transitions to a high-impedance state if an overvoltage (e.g., a negative transient on ground) is detected. The output buffer circuit 106 has an overvoltage input for receiving an overvoltage signal (VDD_OV) provided by the preregulator circuit 102. If VDD_OV has a logic low state, then the output buffer circuit 106 drives the serial data received from the digital core circuitry 114 to OUT. If VDD_OV has a logic high state, then the output of the output buffer circuit 106 is in a high-impedance state.

The preregulator circuit 102 limits the voltage provided to the input buffer circuit 104 and the control circuit 108. The preregulator circuit 102 has an input power terminal coupled to VDD, an output power terminal (VDD_INT) coupled the input buffer circuit 104 and the regulator circuit 112, a reference terminal coupled to IC_GND, and an overvoltage output coupled to the output buffer circuit 106. If the voltage between VDD and IC_GND is less than a first threshold (e.g., 5.5 volts), then the preregulator circuit 102 passes the voltage at VDD to VDD_INT, and provides VDD_OV in a logic low state. if the voltage between VDD and IC_GND is greater than a second threshold (e.g., 6 volts), then the preregulator circuit 102 limits the voltage at VDD_INT to the second threshold, and provides VDD_OV in a logic high state. Accordingly, if the voltage on IC_GND drops due to a negative transient, the preregulator circuit 102 limits the voltage on VDD_INT to voltage suitable for operation of the high-side switch circuit 100.

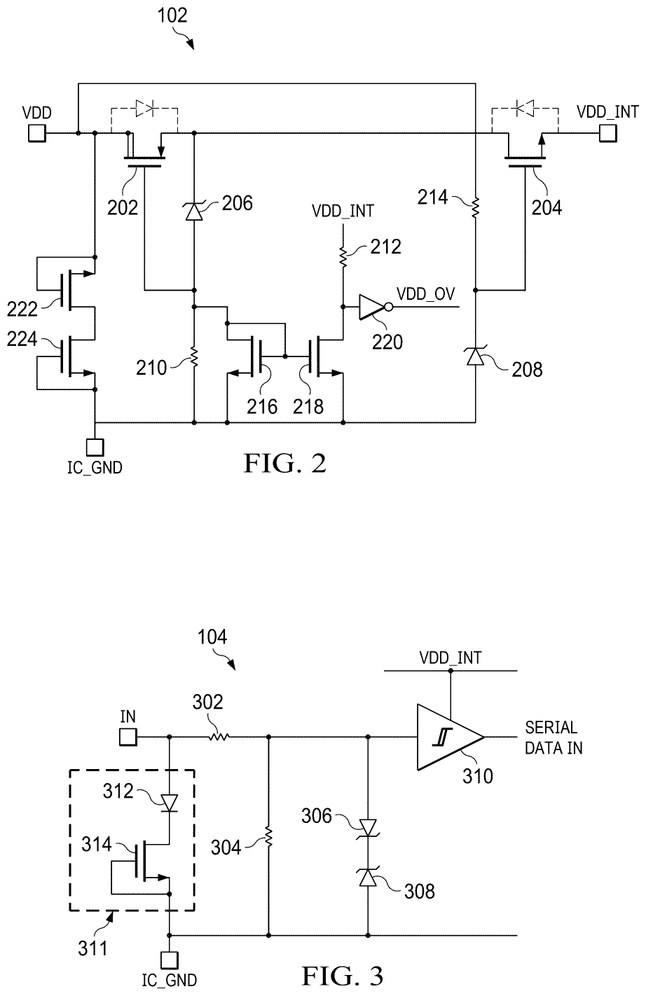

FIG. 2 is schematic diagram of an example preregulator circuit 102 suitable for use in the high-side switch circuit 100. The preregulator circuit 102 includes transistors 202, 204, 216, 218, 222, and 224, Zener diodes 206 and 208, resistors 210, 212, and 214, and an inverter 220. The transistor 202 may be a p-channel field effect transistor (PFET). The transistors 204, 216, 218, 222, and 224 may be NFETs. The transistor 204 may be a high voltage (e.g., 65 volt) transistor, and the transistor 202 may be a lower voltage (e.g., 12 volt) transistor. The transistor 204 may be a natural NFET to reduce voltage drop. The transistor 202 has a first terminal (e.g., drain) coupled to VDD. A second terminal (e.g., source) of the transistor 202 is coupled to the control terminal (e.g., gate) of the transistor 202 via the Zener diode 206. A cathode of the Zener diode 206 is coupled to the second terminal of the transistor 202, and an anode of the Zener diode 206 is coupled to the control terminal of the transistor 202. The resistor 210 is coupled between the control terminal of the transistor 202 and IC_GND. A voltage is developed across the resistor 210 based on the current flowing through the Zener diode 206 to control the transistor 202. Accordingly, the transistor 202 is controlled based on the reverse breakdown voltage of the Zener diode 206.

The transistor 204 has a first terminal (e.g., drain) coupled to the second terminal of the transistor 202, a second terminal (e.g., source) coupled to VDD_INT, and a control terminal (e.g., gate) coupled to VDD via the resistor 214. A first terminal of the resistor 214 is coupled to VDD and a second terminal of the resistor 214 is coupled to the control terminal of the transistor 204. The Zener diode 208 is coupled between the control terminal of the transistor 204 and IC_GND. A voltage is provided across the Zener diode 208 based on the current flowing through the Zener diode 208 to control the transistor 204.

Accordingly, the transistor 204 is controlled based on the reverse breakdown voltage of the Zener diode 208. In some examples of the 102, the Zener diodes 206 and 208 may have a reverse breakdown voltage of about 5.8 volts.

The transistor 202 and the transistor 204 form a back-to-back switch that isolates VDD_INT from VDD. If the voltage between VDD and IC_GND is less than the first threshold, then the transistor 202 and the transistor 204 pass the voltage at VDD to the VDD_INT. If the voltage between VDD and IC_GND is greater than the second threshold, then the transistor 204 operates in saturation mode and limits the voltage at VDD_INT to the second threshold.

The transistor 216 and the transistor 218 are coupled as a current mirror. The transistor 216 has a first terminal (e.g., drain) coupled to the anode of the Zener diode 206, a second terminal (e.g., source) coupled to IC_GND, and a control terminal coupled to the first terminal of the transistor 216. The transistor 218 has a first terminal (e.g., drain) coupled to VDD_INT via the resistor 212, a second terminal coupled to IC_GND, and a control terminal coupled to the control terminal of the transistor 216. The inverter 220 has an input coupled to the first terminal of the transistor 218 and an output coupled to the overvoltage output of the preregulator circuit 102. If current flows through the Zener diode 206, then a portion of the current flows through the transistor 216, and the transistor 218 pulls down the input of the inverter 220 to set VDD_OV to a logic high. If no current flows through the Zener diode 206, then the resistor 212 pulls up the input of the inverter 220 to set VDD_OV to a logic low.

The transistors 222 and 224 are coupled in series between VDD and IC_GND for electrostatic discharge protection. A first terminal (e.g., drain) of the transistor 222 is coupled to a first terminal (e.g., drain) of the transistor 224. A second terminal (e.g., source) of the transistor 222 is coupled to a control terminal (e.g., gate) of the transistor 222 and to VDD. A second terminal (e.g., source) of the transistor 224 is coupled to a control terminal (e.g., gate) of the transistor 224 and to IC_GND.

FIG. 3 is schematic diagram of an example input buffer circuit 104 suitable for use in the high-side switch circuit 100. The input buffer circuit 104 includes resistors 302 and 304, Zener diodes 306 and 308, a Schmitt trigger circuit 310, and an electrostatic discharge protection circuit 311. The resistor 302 is coupled between an input (IN) of the input buffer circuit 104 and an input of the Schmitt trigger circuit 310. A first terminal of the resistor 302 is coupled to IN and a second terminal of the resistor 302 is coupled to the input of the Schmitt trigger circuit 310. The resistor 302 may have a resistance of about 100 kilo-ohms in some examples of the input buffer circuit 104. The resistance of the resistor 302 is relatively small to reduce the delay in charging the capacitance of the input of the Schmitt trigger circuit 310. The resistor 304 is coupled between the input of the Schmitt trigger circuit 310 and IC_GND. A first terminal of the resistor 304 is coupled to the input of the Schmitt trigger circuit 310 and a second terminal of the resistor 304 is coupled to IC_GND. The resistor 304 may have a resistance of about 2 meg-ohms, in some examples of the input buffer circuit 104.

Input signal (e.g., serial data) received at IN passes through the resistor 302 to the input of the Schmitt trigger circuit 310. The Zener diodes 306 and 308 limit the voltage at the input of the Schmitt trigger circuit 310. The Zener diode 306 has an anode coupled to the input of the Schmitt trigger circuit 310, and a cathode coupled to the cathode of the Zener diode 308. An anode of the Zener diode 308 is coupled to IC_GND. The Zener diodes 306 and 308 may limit the voltage at the input of the Schmitt trigger circuit 310 to about 5 volts in some examples of the input buffer circuit 104.

The Schmitt trigger circuit 310 has a power terminal coupled to VDD_INT, and an output coupled to the control circuit 108. A level shifter circuit (not shown) may be coupled between the Schmitt trigger circuit 310 and the digital core circuitry 114 to provide the output signals of the Schmitt trigger circuit 310 to the digital core circuitry 114 with suitable logic voltages.

The electrostatic discharge protection circuit 311 includes a diode 312 and a transistor 314. An anode of the diode 312 is coupled to the first terminal of the resistor 302. A first terminal (e.g., drain) of the transistor 314 is coupled to the cathode of the diode 312. A second terminal (e.g., source) of the transistor 314 is coupled to a control terminal (e.g., gate) of the transistor 314 and to IC_GND.

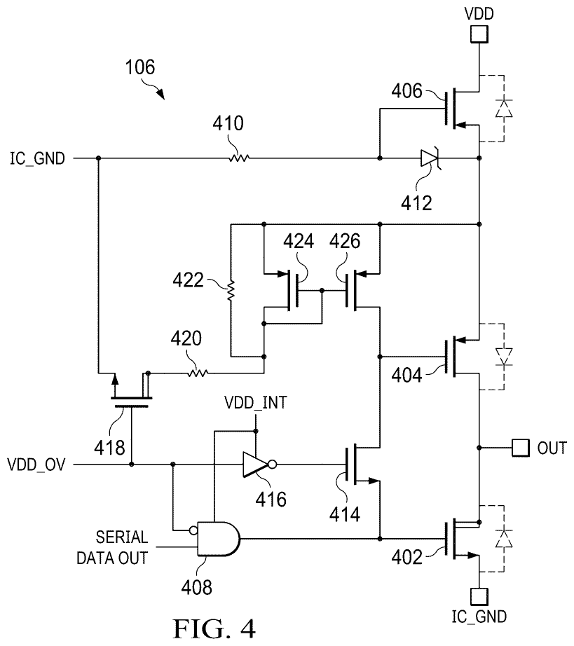

FIG. 4 is schematic diagram of an example output buffer circuit 106 suitable for use in the high-side switch circuit 100. The output buffer circuit 106 includes transistors 402, 404, 406, 414, 418, 424, and 426, resistors 410, 420, and 422, a logic gate 408, a Zener diode 412, and an inverter 416. The transistors 402, 414, and 418 may be NFETs. The transistors 404, 406, 424, and 426 may be PFETs. The transistors 402, 414, and 418 may be high voltage (e.g., 40, 50, or 60 volt) transistors. The transistors 404 and 406 may be low voltage (e.g., 5 volt) transistors. The logic gate 408 has a first input coupled to the output of the digital core circuitry 114 for reception of serial data, and a second input coupled to the overvoltage output of the preregulator circuit 102 for receipt of VDD_OV. If VDD_OV is logic low, then the logic gate 408 passes the serial data for transmission, otherwise the output of the logic gate 408 provides a logic low voltage. The logic gate 408 and the inverter 416 are coupled to VDD_INT.

The transistor 402 has a first terminal (e.g., source) coupled to IC_GND, a second terminal (e.g., drain) coupled to the output of the high-side switch circuit 100 (OUT), and a control terminal (e.g., gate) coupled to the output of the logic gate 408. The transistors 404 and 406 form back-to-back switch. The transistor 404 has a first terminal (e.g., drain) coupled to the second terminal of the transistor 402, and a second terminal (e.g., source) coupled to a first terminal (e.g., source) of the transistor 406. A second terminal (e.g., drain) of the transistor 406 is coupled to VDD. A control terminal (e.g., gate) of the transistor 406 is coupled to the first terminal of the transistor 406 via the Zener diode 412. An anode of the Zener diode 412 is coupled to the control terminal of the transistor 406, and a cathode of the Zener diode 412 is coupled to the first terminal of the transistor 406. The control terminal of the transistor 406 is coupled to IC_GND via the resistor 410. A first terminal of the resistor 410 is coupled to the control terminal of the transistor 406 and a second terminal of the resistor 410 is coupled to IC_GND. The transistor 406 is turned on by the resistor 410 and the Zener diode 412.

The inverter 416 has an input coupled to the second input of the logic gate 408, and an output coupled to the control terminal (e.g., gate) of the transistor 414. A first terminal (e.g., source) of the transistor 414 is coupled to the output of the logic gate 408, and a second terminal (e.g., drain) of the transistor 414 is coupled to the control terminal of the transistor 404. If VDD_OV is logic high, the transistor 402, the transistor 414 and the transistor 404 are turned off, and the output of the output buffer circuit 106 (provided at the second terminal of the transistor 402) is in a high-impedance state.

The transistor 418 has a first terminal (e.g., source) coupled to IC_GND, a second terminal (e.g., drain) coupled to the first terminal of the transistor 406 via the resistors 420 and resistor 422, and a control terminal (e.g., gate) coupled to the second terminal of the logic gate 408. The resistor 420 has a first terminal coupled to the second terminal of the resistor 420, and a second terminal coupled to a first terminal of the resistor 422. A second terminal of the resistor 422 is coupled to the first terminal of the transistor 406. The transistor 424 has a first terminal (e.g., source) coupled to the second terminal of the resistor 422, a second terminal (e.g., drain), and a control terminal (e.g., gate) coupled to the first terminal of the resistor 422. The transistor 426 has a first terminal coupled to the first terminal of the transistor 424, a second terminal coupled to the control terminal of the transistor 404, and a control terminal coupled to the control terminal of the transistor 424. If VDD_OV is logic high, then current flows through the transistor 424 and the transistor 426 to turn off the transistor 404. If VDD_OV is logic low, then the transistor 414 turns the transistor 404 on and off based on the output signal of the logic gate 408.

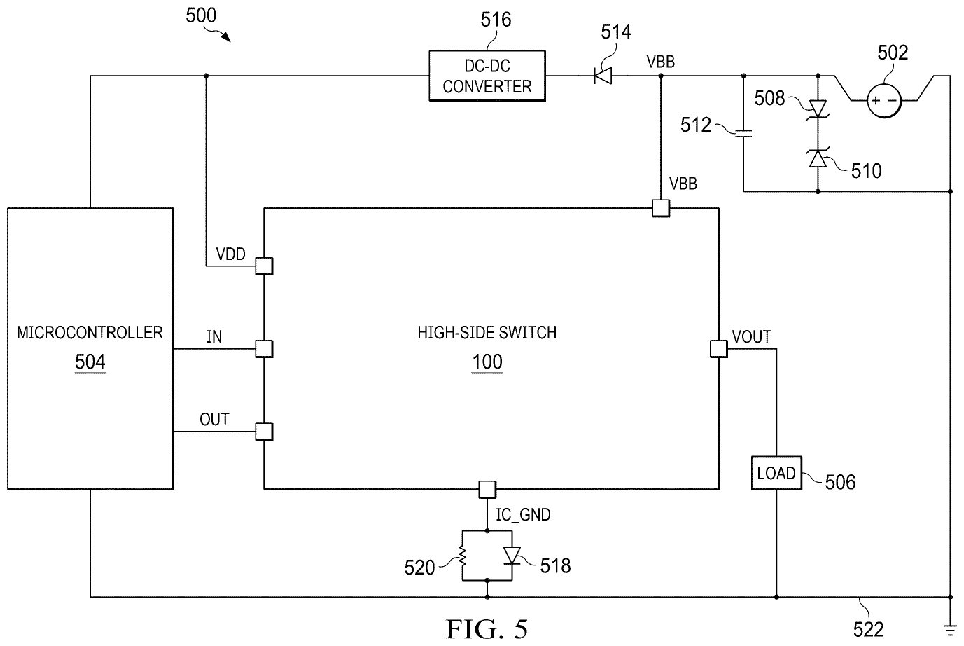

FIG. 5 is a block diagram of an example system 500 that includes the high-side switch circuit 100. The system 500 may be a part of a vehicular system in some examples, where the high-side switch circuit 100 switches power to the load circuit 506, and the load circuit 506 is circuit or device of a vehicle. The system 500 may also be an industrial system, or other type of system. In the system 500, a voltage source 502 (e.g., a battery) provides power. A first terminal of the voltage source 502 is coupled to a ground 522, and a second terminal of the voltage source 502 provides a voltage VBB. Transient voltage suppressor (TVS) diodes 508 and 510 are coupled in series between the first and second terminals of the voltage source 502 to limit the voltage across the voltage source 502. A capacitor 512 is also coupled across the voltage source 502 to filter VBB. The first terminal of the voltage source 502 is coupled to a reference terminal of a controller 504 and the load circuit 506, and to the IC_GND of the high-side switch circuit 100 via a resistor 520 and a diode 518. A DC-DC converter 516 is coupled to the second terminal of the voltage source 502 via a diode 514. The DC-DC converter 516 generates voltage VDD based on VBB. The DC-DC converter 516 may be a step-down converter in some examples of the system 500. The output of the DC-DC converter 516 is coupled to power terminals of the high-side switch circuit 100 and the controller 504. A power terminal of the load circuit 506 is coupled to an output terminal of the high-side switch circuit 100.

The controller 504 is coupled to the high-side switch circuit 100 and communicates with the high-side switch circuit 100 via the serial bus. The controller 504 has an output for providing serial data to the high-side switch circuit 100, and an input for receiving serial data from the high-side switch circuit 100. The high-side switch circuit 100 includes the preregulator circuit 102, the input buffer circuit 104, and the output buffer circuit 106 as described herein. The high-side switch circuit 100 enables serial communication with the controller 504 at a rate of 8 mega-bits per second or higher because no current limiting resistors are needed between the controller 504 and the high-side switch circuit 100. Additionally, because VDD_INT is isolated from VDD by the preregulator circuit 102, current leakage from VDD during a transient may be limited (e.g., less than 2 milli-amperes), and the voltage on VDD maintained so as to provided proper operation of the controller 504 and other circuits coupled to VDD. No current limiting resistor is needed at the connection of VDD to the high-side switch circuit 100, which lowers drop in the voltage on VDD. Transient response time in the high-side switch circuit 100 may be low because passive devices are used to implement protection. Transient protection in the high-side switch circuit 100 may be implemented without biasing, which allows for protection during power-up and low power modes (e.g., sleep mode) of the high-side switch circuit 100.

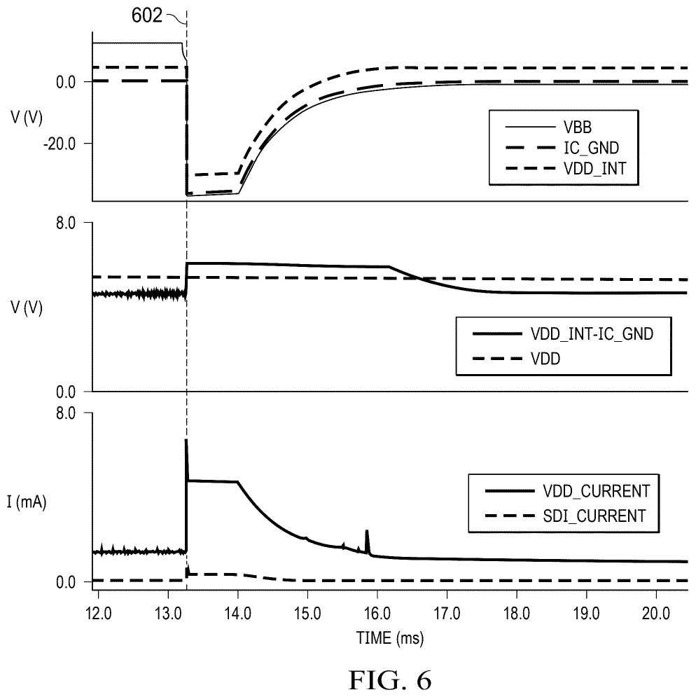

FIG. 6 is a graph of example signals in the system 500. In FIG. 6, the voltage VBB provided by the voltage source 502, the voltage on IC_GND, the voltage on VDD_INT, the voltage on VDD, the current drawn from VDD (VDD_CURRENT), and the current drawn by the input buffer circuit 104 through IN (SDI_CURRENT) are shown. At time 602, the voltage VBB drops from about 14 volts to less than-36 volts (e.g.,-60 volts). The TVS diodes 508 and 510 clamp VBB to about-36 volts in FIG. 6. Other systems may implement a different clamp voltage. IC_GND drops to about-36 volts with VBB, and the preregulator circuit 102 holds the voltage at VDD_INT to about 6 volts above IC_GND. FIG. 6 shows that the voltage between VDD_INT and IC_GND increases slightly (e.g., about 1.5 volts) with the transient on VBB, and the voltage on VDD remains relatively constant. The current drawn from VDD and from the serial input of the high-side switch circuit 100 increases slightly (e.g., VDD current increases by about 3 milliamperes (ma) and SDI_CURRENT increases by less than 1 ma. Accordingly, the high-side switch circuit 100 protects the controller 504 by maintaining VDD voltage, and maintains internal voltage (VDD_INT voltage) suitable for operation during the negative transient on VBB.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a first transistor having a first terminal, a second terminal, and a control terminal;
a first Zener diode having a first terminal coupled to the second terminal of the first transistor, and a second terminal coupled to the control terminal of the first transistor;
a second transistor having a first terminal coupled to the second terminal of the first transistor, a second terminal, and a control terminal coupled to the first terminal of the first transistor; and
a second Zener diode having a first terminal coupled to the control terminal of the second transistor, and a second terminal coupled to the second terminal of the first Zener diode.

2. The circuit of claim 1, further comprising:
a resistor coupled between the control terminal of the first transistor and the second terminal of the second Zener diode; and
a resistor coupled between the first terminal of the first transistor and the control terminal of the second transistor.

3. The circuit of claim 1, further comprising:
a third transistor having a first terminal coupled to the control terminal of the first transistor, a second terminal coupled to the second terminal of the second Zener diode, and a control terminal coupled to the first terminal of the third transistor; and
a fourth transistor having a first terminal coupled to the second terminal of the second transistor, a second terminal coupled to the second terminal of the third transistor, and a control terminal coupled to the control terminal of the third transistor.

4. The circuit of claim 3, further comprising a resistor coupled between the second terminal of the second transistor and the first terminal of the fourth transistor.

5. The circuit of claim 3, further comprising an output buffer circuit including:
a fifth transistor having a first terminal coupled to the second terminal of the second Zener diode, a second terminal, and a control terminal;
a sixth transistor having a first terminal coupled to the second terminal of the fifth transistor, a second terminal, and a control terminal;
a seventh transistor having a first terminal coupled to the second terminal of the sixth transistor, a second terminal coupled to the first terminal of the first transistor, and a control terminal; and
a logic gate having a first input configured to receive an output signal, a second input coupled to the second terminal of the fourth transistor, and an output coupled to the control terminal of the fifth transistor.

6. The circuit of claim 5, wherein the output buffer circuit includes:
a third Zener diode having a cathode coupled to the first terminal of the seventh transistor, and an anode coupled to the control terminal of the seventh transistor; and
a resistor coupled between the control terminal of the seventh transistor and the first terminal of the fifth transistor.

7. The circuit of claim 5, wherein the output buffer circuit includes:
an eighth transistor having a first terminal coupled to the control terminal of the fifth transistor, a second terminal coupled to the control terminal of the sixth transistor; and a control terminal coupled to the second input of the logic gate;
a ninth transistor having a first terminal coupled to the first terminal of the fifth transistor, a second terminal, and a control terminal coupled to the second input of the logic gate;
a first resistor having a first terminal coupled to the second terminal of the ninth transistor, and a second terminal;
a second resistor having a first terminal coupled to the second terminal of the first resistor, and a second terminal coupled to the second terminal of the sixth transistor;
a tenth transistor having a first terminal coupled to the first terminal of the second resistor, a second terminal coupled to the second terminal of the second resistor, and a control terminal coupled to the first terminal of the tenth transistor; and
an eleventh transistor having a first terminal coupled to the control terminal of the sixth transistor, a second terminal coupled to the second terminal of the tenth transistor, and a control terminal coupled to the control terminal of the tenth transistor.

8. The circuit of claim 1, further comprising an input buffer circuit including:
an input terminal configured to receive an input signal;
a first resistor having a first terminal coupled to the input terminal, and a second terminal;
a second resistor having a first terminal coupled to the second terminal of the first resistor, and a second terminal coupled to the second terminal of the second Zener diode;
a third Zener diode having an anode coupled to the second terminal of the first resistor, and a cathode;
a fourth Zener diode having a cathode coupled to the cathode of the third Zener diode, and an anode coupled to second terminal of the second resistor; and
a Schmitt trigger circuit having an input coupled to the second terminal of the first resistor, an output, and a power terminal coupled to the second terminal of the second transistor.

9. The circuit of claim 8, wherein the input buffer circuit includes:
an electrostatic discharge protection circuit including:
a diode having an anode coupled to the first terminal of the first resistor, and a cathode; and
a third transistor having a first terminal coupled to the anode of the diode, a second terminal coupled to the second terminal of the second resistor, and a control terminal coupled to the second terminal of the third transistor.

10. A circuit comprising:
a preregulator circuit having a first terminal configured to receive a power supply voltage, a second terminal configured to receive a reference voltage, a first output configured to provide a regulated voltage, and a second output configured to provide an overvoltage signal;
an output buffer circuit including:
a first transistor having a first terminal coupled to the second terminal of the preregulator circuit, a second terminal, and a control terminal;
a second transistor having a first terminal coupled to the second terminal of the first transistor, a second terminal, and a control terminal;
a third transistor having a first terminal coupled to the second terminal of the second transistor, a second terminal coupled to the first terminal of the preregulator circuit, and a control terminal;
a resistor having a first terminal coupled to the second terminal of the preregulator circuit, and a second terminal coupled to the control terminal of the third transistor; and
a logic gate having a first input configured to receive an output signal, a second input coupled to the second output of the preregulator circuit, and an output coupled to the control terminal of the first transistor.

11. The circuit of claim 10, wherein the output buffer circuit includes a Zener diode having a cathode coupled to the first terminal of the third transistor, and an anode coupled to the control terminal of the third transistor.

12. The circuit of claim 10, wherein:
the resistor is a first resistor; and
the output buffer circuit includes:
a fourth transistor having a first terminal coupled to the control terminal of the first transistor, a second terminal coupled to the control terminal of the second transistor; and a control terminal coupled to the second input of the logic gate;
a fifth transistor having a first terminal coupled to the second terminal of the preregulator circuit, a second terminal, and a control terminal coupled to the second input of the logic gate;
a second resistor having a first terminal coupled to the second terminal of the fifth transistor, and a second terminal;
a third resistor having a first terminal coupled to the second terminal of the second resistor, and a second terminal coupled to the second terminal of the second transistor;
a sixth transistor having a first terminal coupled to the first terminal of the third resistor, a second terminal coupled to the second terminal of the third resistor, and a control terminal coupled to the first terminal of the sixth transistor; and
a seventh transistor having a first terminal coupled to the control terminal of the second transistor, a second terminal coupled to the second terminal of the sixth transistor, and a control terminal coupled to the control terminal of the sixth transistor.

13. The circuit of claim 10, wherein:
the resistor is a first resistor; and
the circuit includes an input buffer circuit, the input buffer circuit including:
an input terminal configured to receive an input signal;
a second resistor having a first terminal coupled to the input terminal, and a second terminal;
a third resistor having a first terminal coupled to the second terminal of the second resistor, and a second terminal coupled to the second terminal of the preregulator circuit;
a first Zener diode having an anode coupled to the second terminal of the second resistor, and a cathode;
a second Zener diode having a cathode coupled to the cathode of the first Zener diode, and an anode coupled to second terminal of the third resistor; and
a Schmitt trigger circuit having an input coupled to the second terminal of the second resistor, an output, and a power terminal coupled to the output of the preregulator circuit.

14. The circuit of claim 13, wherein the input buffer circuit includes:
an electrostatic discharge protection circuit including:
a diode having an anode coupled to the first terminal of the first resistor, and a cathode; and
a fourth transistor having a first terminal coupled to the anode of the diode, a second terminal coupled to the second terminal of the third resistor, and a control terminal coupled to the second terminal of the fourth transistor.

15. The circuit of claim 10, wherein the preregulator circuit includes:
a fourth transistor having a first terminal coupled to the first terminal of the preregulator circuit, a second terminal, and a control terminal;
a first Zener diode having a first terminal coupled to the second terminal of the fourth transistor, and a second terminal coupled to the control terminal of the fourth transistor;
a fifth transistor having a first terminal coupled to the second terminal of the fourth transistor, a second terminal, and a control terminal coupled to the first terminal of the fourth transistor; and
a second Zener diode having a first terminal coupled to the control terminal of the fifth transistor, and a second terminal coupled to the second terminal of the preregulator circuit.

16. The circuit of claim 15, wherein:
the resistor is a first resistor; and
the preregulator circuit includes:
a second resistor coupled between the control terminal of the fourth transistor and the second terminal of the second Zener diode; and
a third resistor coupled between the first terminal of the fourth transistor, and the control terminal of the fifth transistor.

17. The circuit of claim 15, wherein the preregulator circuit includes
a sixth transistor having a first terminal coupled to the control terminal of the fourth transistor, a second terminal coupled to the second terminal of the second Zener diode, and a control terminal coupled to the first terminal of the fifth transistor; and
a seventh transistor having a first terminal coupled to the second terminal of the fifth transistor, a second terminal coupled to the second terminal of the sixth transistor, and a control terminal coupled to the control terminal of the sixth transistor.

18. The circuit of claim 17, wherein the preregulator circuit includes a resistor coupled between the second terminal of the fifth transistor and the first terminal of the seventh transistor.

19. A high-side switch circuit comprising:
a high-side transistor having a first terminal configured to receive a first voltage, a second terminal configured to provide a second voltage to a load circuit; and
a control terminal;
a control circuit having a first output coupled to the control terminal of the high-side transistor; a second output, and an input;
a preregulator circuit having a first terminal configured to receive a first voltage and a second terminal configured to provide a second voltage, the preregulator circuit configured to pass the first voltage to the second terminal based on the first voltage being less than a first threshold, and limit the second voltage at the second terminal to a second threshold based on the first voltage being greater than the second threshold;
an input buffer circuit having a power terminal coupled to the second terminal of the preregulator circuit, and an output coupled to the input of the control circuit; and
an output buffer circuit having a power terminal coupled to the first terminal of the preregulator circuit, and an input coupled to the second output of the control circuit.

20. The high-side switch circuit of claim 19, wherein:
the preregulator circuit has an output configured to provide an overvoltage signal, and the preregulator circuit is configured to provide the overvoltage signal in a first state based on the first voltage being less than the first threshold, and provide the overvoltage signal in a second state based on the first voltage being greater than the second threshold; and
the output buffer circuit has an output configured to:
provide a signal received at the input of the output buffer circuit based on the overvoltage signal having the first state, and
transition to a high-impedance state based on the overvoltage signal having the second state.
